(19) United States
(12) Patent Application Publication
(10) Pub. No.: US 2024/0387458 A1
(43) Pub. Date: Nov. 21, 2024

(54) Three-Dimensional Vertical Interconnect Architecture and Methods For Forming

(71) Applicant: Applied Materials, Inc., Santa Clara, CA (US)

(72) Inventors: Suketu PARIKH, San Jose, CA (US); Andrew YEOH, Portland, OR (US); Arvind SUNDARRAJAN, Singapore (SG); Nirmalya MAITY, Menlo Park, CA (US); Balasubramanian PRANATHARTHIHARAN, San Jose, CA (US); Martinus Maria BERKENS, Eindhoven (NL)

(21) Appl. No.: 18/199,183

(22) Filed: May 18, 2023

(51) Int. Cl. H01L 25/065; H01L 21/768; H01L 21/78; H01L 23/00; H01L 23/367; H01L 23/522; H01L 25/00

(52) U.S. Cl. CPC H01L 25/0657; H01L 21/7684; H01L 21/78; H01L 23/3672; H01L 23/5226; H01L 24/80; H01L 25/50; H01L 24/08; H01L 24/16; H01L 2224/08145; H01L 2224/16225; H01L 2224/80895; H01L 2224/80896

(57) ABSTRACT

In some embodiments, a method for forming a multiple die stack comprises forming a first circuit wafer with multiple first circuit dies and a first circuit support layer on a bottom of the first circuit wafer where each first circuit die has a power and circuit layer underlying a power and signal layer, forming an interposer wafer with multiple interposer dies and an interposer support layer on a top of the interposer wafer where each interposer die has a power and signal layer underlying a power via and signal via layer, and hybrid bonding a top surface of the first circuit wafer to a bottom surface of the interposer wafer to form a first bonded wafer with electrical power and signal connections between the multiple first circuit dies and the multiple interposer dies where the interposer wafer provides structural support of the first bonded wafer during subsequent processing.

### FIELD

Embodiments of the present principles generally relate to processing of semiconductor substrates.

### BACKGROUND

Advances in artificial intelligence have put ever increasing pressure on logic and memory circuits to keep up with the computational requirements. As chip processing speeds increase, the amount of time required to store and retrieve information from memory becomes a bottleneck in machine learning systems. The inventors have observed that the parallel arrangement of logic and memory devices has a profound impact on the storage and retrieval time for memory data.

Accordingly, the inventors have provided an architecture and methods of forming that substantially decrease the storage and retrieval time for data, increasing machine learning system processing speeds.

### SUMMARY

Architectures and methods for forming that substantially decrease memory storage and retrieval times are provided herein.

In some embodiments, a method for forming a multiple die stack may comprise forming a first circuit wafer with multiple first circuit dies and a first circuit support layer on a bottom of the first circuit wafer where each first circuit die has a power and circuit layer underlying a power and signal layer, forming an interposer wafer with multiple interposer dies and an interposer support layer on a top of the interposer wafer where each interposer die has a power and signal layer underlying a power via and signal via layer, and hybrid bonding a top surface of the first circuit wafer to a bottom surface of the interposer wafer to form a first bonded wafer with electrical power and signal connections between the multiple first circuit dies and the multiple interposer dies, wherein the interposer wafer provides structural support of the first bonded wafer during subsequent processing.

In some embodiments, the method may further include flipping the first bonded wafer to expose the first circuit support layer of the first circuit wafer and performing a first chemical mechanical polishing (CMP) process or a first etching process on the first circuit wafer to remove the first circuit support layer to expose a plurality of power vias in the power and circuit layer of the first circuit wafer, forming a power delivery network (PDN) layer directly on the first circuit wafer, the PDN layer having a top surface with internal power contacts interfacing with the power and circuit layer of the first circuit wafer and a bottom surface with external power contacts, wherein the internal power contacts of the PDN layer make contact with the power and circuit layer to electrically connect the internal power contacts of the PDN layer to the plurality of power vias in the power and circuit layer of the first circuit wafer to form a second bonded wafer from the first bonded wafer, and/or flipping the second bonded wafer to expose the top surface of the interposer wafer and performing a second CMP process or a second etching process on the interposer support layer to expose contact points of the power via and signal via layer of the interposer wafer.

In some embodiments, the method may further include reducing the interposer wafer to a total thickness of approximately 100 microns to approximately 200 microns when using vias with a critical dimension of approximately 5 microns to approximately 20 microns, reducing the interposer wafer to a total thickness of approximately 5 microns to approximately 10 microns when using vias with a critical dimension of approximately 2 microns to approximately 4 microns, forming a second circuit wafer with multiple second circuit dies, each second circuit die having a bottom surface with at least one signal contact and at least one power contact for electrically interconnecting with the multiple interposer dies of the interposer wafer, hybrid bonding the bottom surface of the second circuit wafer to the top surface of the interposer wafer to form a third bonded wafer from the second bonded wafer to electrically connect the at least one signal contact and the at least one power contact to the multiple interposer dies of the interposer wafer and dicing the third bonded wafer to form electrically connected vertical die stacks, each vertical die stack has one portion of the PDN layer, one of the first circuit die, one of the interposer die, and one of the second circuit die to form a complete vertical die stack with backside power capability, and/or forming a heatsink in contact with the second circuit die to remove heat from underlying circuits.

In some embodiments, the method may further include forming at least one heat sink for an external power contact of the PDN layer in a substrate with contacts for electrically connecting with the PDN layer and electrically connecting the PDN layer to the substrate, dicing the second bonded wafer after performing the second CMP process or the second etching process to form partial vertical die stacks that are electrically connected from the second bonded wafer, dicing the second circuit wafer to form second circuit dies, and hybrid bonding one of the second circuit dies to one of the partial vertical die stacks to form a complete vertical die stack with backside power capability, forming a heatsink in contact with the second circuit die to remove heat from underlying circuits, and/or forming at least one heat sink for an external power contact of the PDN layer in a substrate with contacts for electrically connecting with the PDN layer and electrically connecting the PDN layer to the substrate.

In some embodiments, a method for forming a multiple die stack may include forming a first circuit wafer with multiple first circuit dies and a first circuit support layer on a bottom of the first circuit wafer where each first circuit die has a power and circuit layer underlying a power and signal layer, forming an interposer wafer with multiple interposer dies and an interposer support layer on a top of the interposer wafer where each interposer die has a power and signal layer underlying a power via and signal via layer, hybrid bonding a top surface of the first circuit wafer to a bottom surface of the interposer wafer to form a first bonded wafer with electrical power and signal connections between the multiple first circuit dies and the multiple interposer dies where the interposer wafer provides structural support of the first bonded wafer during subsequent processing, flipping the first bonded wafer to expose the first circuit support layer of the first circuit wafer, performing a first chemical mechanical polishing (CMP) process or a first etching process on the first circuit wafer to remove the first circuit support layer to expose a plurality of power vias in the power and circuit layer of the first circuit wafer, forming a power delivery network (PDN) layer directly on the first circuit wafer, the PDN layer having a top surface with internal power contacts interfacing with the power and circuit layer of the first circuit wafer and a bottom surface with external power contacts where the internal power contacts of the PDN layer make contact with the power and circuit layer to electrically connect the internal power contacts of the PDN layer to the plurality of power vias in the power and circuit layer of the first circuit wafer to form a second bonded wafer from the first bonded wafer, flipping the second bonded wafer to expose the top surface of the interposer wafer, performing a second CMP process or a second etching process on the interposer support layer to expose contact points of the power via and signal via layer of the interposer wafer such that a thickness of the interposer wafer is approximately 100 microns to approximately 200 microns, forming a second circuit wafer with multiple second circuit dies, each second circuit die having a bottom surface with at least one signal contact and at least one power contact for electrically interconnecting with the multiple interposer dies of the interposer wafer, hybrid bonding the bottom surface of the second circuit wafer to the top surface of the interposer wafer to form a third bonded wafer from the second bonded wafer to electrically connect the at least one signal contact and the at least one power contact to the multiple interposer dies of the interposer wafer and dicing the third bonded wafer to form electrically connected vertical die stacks, each vertical die stack has one portion of the PDN layer, one of the first circuit die, one of the interposer die, and one of the second circuit die to form a complete vertical die stack with backside power capability.

In some embodiments, the method may further include forming a heatsink in contact with the second circuit die to remove heat from underlying circuits and/or forming at least one heat sink for an external power contact of the PDN layer in a substrate with contacts for electrically connecting with the PDN layer, and electrically connecting the PDN layer to the substrate.

In some embodiments, a die stack with a vertical architecture may comprise a power delivery network (PDN) layer with a first backside power path and a first circuit power path, a first circuit die with a first circuit, a second circuit power path electrically connected to the first circuit and the first circuit power path of the PDN layer, a second backside power path electrically connected to the first backside power path of the PDN layer, and a first signal path electrically connected to the first circuit, an interposer die with a third backside power path electrically connected to the second backside power path of the first circuit die and a second signal path electrically connected to the first signal path of the first circuit die, and a second circuit die with a power contact electrically connected to the third backside power path of the interposer die and a signal contact electrically connected to the second signal path of the interposer die.

In some embodiments, the die stack may further comprise an interposer die that further includes a signal altering element interposed in the second signal path that electrically alters signal characteristics of signals traveling on the second signal path prior to reaching the second circuit die, a first circuit die that includes a plurality of first circuits and a plurality of first signal paths and a plurality of second circuit power paths and wherein the PDN layer includes a plurality of first circuit power paths that are electrically connected to the plurality of second circuit power paths in the first circuit die, and/or a heatsink in thermal contact with a top surface of the second circuit die.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a cross-sectional view of a backside power delivery architecture in accordance with some embodiments of the present principles.

FIG. 2 depicts a cross-sectional view of a backside power delivery architecture with heatsinks in accordance with some embodiments of the present principles.

FIGS. 3A-3B are a method of forming a backside power delivery architecture in accordance with some embodiments of the present principles.

FIG. 4 depicts an isometric view and a top-down view of a first circuit wafer and a cross-sectional view of a first circuit die in accordance with some embodiments of the present principles.

FIG. 5 depicts an isometric view and a top-down view of an interposer wafer and a cross-sectional view of an interposer die in accordance with some embodiments of the present principles.

FIG. 6 depicts an isometric view and a cross-sectional view of an interposer wafer bonded to a first circuit wafer to form a bonded wafer in accordance with some embodiments of the present principles.

FIG. 7 depicts cross-sectional views of flipping a bonded wafer and removing a portion of a first circuit wafer in accordance with some embodiments of the present principles.

FIG. 8 depicts an isometric view and a top-down view of a backside power delivery network layer formed on a first circuit wafer and a cross-sectional view of a backside power delivery network layer in accordance with some embodiments of the present principles.

FIG. 9 depicts cross-sectional views of flipping a bonded wafer and removing a portion of an interposer wafer in accordance with some embodiments of the present principles.

FIG. 10 depicts an isometric view and a top-down view of a second circuit wafer and a cross-sectional view of a second circuit die in accordance with some embodiments of the present principles.

FIG. 11 depicts an isometric view and a cross-sectional view of a second circuit wafer bonded to an interposer wafer to form a bonded wafer in accordance with some embodiments of the present principles.

FIG. 12 depicts an isometric view and a top-down view of a bonded wafer of a power delivery network layer, a first circuit wafer, an interposer wafer, and a second circuit wafer singulated into a cross-sectional view of separate dies in accordance with some embodiments of the present principles.

FIG. 13 depicts isometric views and cross-sectional views of a bonded wafer of a power delivery network layer, a first circuit wafer, and an interposer wafer singulated into a separate die stack before a singulated second circuit die is bonded to the die stack in accordance with some embodiments of the present principles.

FIG. 14 depicts a cross-sectional view of a vertical stack with additional dies in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Architectures and methods for forming the architectures provide a multiple chip vertical and local interconnect. The methods feature wafer level flows to create backside power rail connections and combine silicon (Si) interposers for creating multiple chip interconnects. By forming vertical connections, the architecture minimizes RC delay between logic and memory devices, providing an innovative design for artificial intelligence (AI)/machine learning (ML) and neuromorphic applications. RC delay improvements provided by the present architecture may have 50 to 100 times or more in reduction in RC delay over traditional parallel type architectures. The architecture of the present methods allows vertical interconnections between logic and memory built on separate chips (from separate wafers), reducing the interconnect distance from a few centimeters or more to a few microns or less. The narrow pitch of the vertical interconnects with local connections beneficially allows for increased connection density, allowing more iterations or calculations to be possible over traditional architectures.

Current connections of multiple laterally situated chips require a combination of through silicon via (TSV) and wire bonding, resulting in long lateral interconnects from chip to chip (e.g., a typical size of a chip=1-20 mm). Thus, resulting in a large RC delay as well as a limited number of possible connections. The present principles combine backside power rail chip connections plus a novel Si interposer that provides a high density of vertical connections and is also used as support during formation of the vertical chip stack. The present architecture allows for high density connections between logic and memory devices by using a Si interposer that provides short (less than 200 microns) direct vertical connections. The power connections are nano TSV sized connections between the logic and power delivery network (PDN) to the substrate and can be formed using back-end-of-line (BEOL) processes.

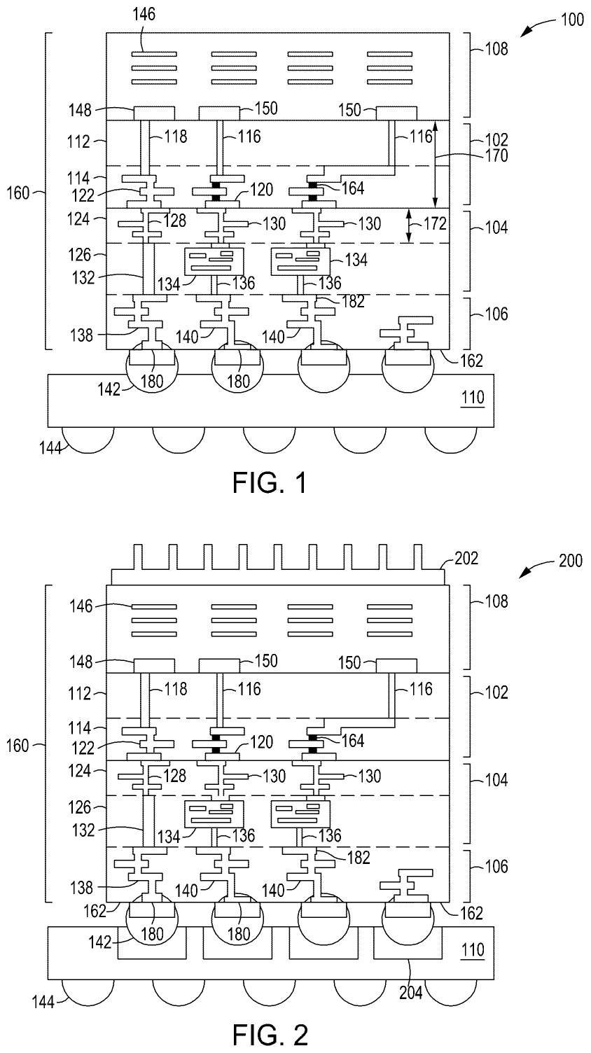

FIG. 1 depicts a cross-sectional view of a vertical stack architecture 100 in accordance with some embodiments. As used herein a ‘die’ is a portion of a wafer that may contain passive elements, active elements, signal connections, redistribution layers (RDLs), vias, and/or power connections and the like. In general, a die is replicated many times on a single wafer. In methods disclosed herein, multiple wafers are bonded together along with a layer that is formed on a wafer and then eventually singulated to form a vertical stack 160 of the vertical stack 160. The formation processes are discussed below. The vertical stack 160 includes a PDN layer 106 that uses RDLs to distribute power from the backside or bottom 162 of the vertical stack 160 to all dies in the stack. The PDN layer 106 includes one or more feedthrough power connection 138 that provides power from an external power contact 180 to upper dies via an internal power contact 182 and one or more local power connection 140 that provides power from the external power contact 180 to a die located above the PDN layer 106 via the internal power contact 182. In some embodiments, the PDN layer 106 may have a vertical thickness of approximately 1 micron to approximately 2 microns. Solder bumps 142 may be attached to the PDN layer 106 for external power connections, such as for example, to a substrate 110 that may be used to support one or more vertical stack architectures. The substrate 110 may have additional solder bumps 144 to allow for other external connections to the stack.

The PDN layer 106 is formed on a wafer that contains a first circuit die 104. The first circuit die 104 includes a power distribution and circuit layer 126 and a power distribution and signal layer 124. In some embodiments, the first circuit die 104 may be a logic circuit and the like or a processor circuit and the like. The power distribution and circuit layer 126 incudes one or more feedthrough power via 132 electrically connected to the feedthrough power connection 138 of the PDN layer 106, one or more first circuit power via 136 electrically connected to the local power connection 140, and one or more first circuit 134 electrically connected to the local power connection 140. In some embodiments, the first circuit power vias 136 are nano-sized connections between the first circuit 134 and the PDN layer 106. The power distribution and signal layer 124 includes one or more feedthrough power connection 128 electrically connected to the feedthrough power via 132 and one or more signal connection 130 electrically connected to the first circuit 134. The first circuit die 104 is bonded to the interposer die 102.

In some embodiments, the interposer die 102 is formed of a low-k dielectric material with copper interconnects and the like. The interposer die 102 includes a power and signal connection layer 114 that includes one or more feedthrough power connection 122 and one or more signal connection 120 with signal altering elements 164. The signal altering elements 164 may include, but are not limited to, resistive elements, inductive elements, and/or capacitive elements and the like that aid in adjusting signal characteristics of signals from the first circuit 134 being sent to dies above the first circuit die 104 (e.g., signals from the first circuit 134 traversing the interposer die 102 to the second circuit die 108, etc.). The signal connection 120 is electrically connected to the signal connection 130 of the first circuit die 104. The feedthrough power connection 122 is electrically connected to the feedthrough power connection 128 of the first circuit die 104.

The interposer die 102 also includes a power and signal via layer 112 that has a feedthrough power via 118 to supply power from the PDN layer 106 to an upper die such as, for example, the second circuit die 108. The feedthrough power via 118 is electrically connected to the feedthrough power connection 122. The power and signal via layer 112 also includes one or more signal vias 116 which are electrically connected to the signal connection 120 to supply signals to an upper die such as, for example, the second circuit die 108. In some embodiments, the signal vias 116 may have a CD of approximately 5 microns to approximately 20 microns to provide a high-density level of connections between the first circuit 134 and the second circuit 146. The second circuit die 108 is bonded to the interposer die 102. The second circuit die 108 includes a power contact 148 that is electrically connected to the feedthrough power via 118 of the interposer die 102. The feedthrough power connection 138, the feedthrough power via 132, the feedthrough power connection 128, the feedthrough power connection 122, and the feedthrough power via 118 act in concert to deliver power to the second circuit die 108 from the PDN layer 106 in a backside power delivery architecture.

The second circuit die 108 also includes one or more signal contact 150 that is electrically connected to the signal via 116 of the interposer die 102. In some embodiments, the second circuit die 108 is a memory device and the like or a processor or logic device and the like. The signal connection 130, the signal connection 120, and the signal via 116 act in concert to deliver and receive signals (and alter signal characteristics if necessary for compatibility) to and from the first circuit 134 and the second circuit 146 of the second circuit die 108. In some embodiments, the thickness 170 of the interposer die 102 may be from approximately 100 microns to approximately 300 microns. In some embodiments, the thickness 170 of the interposer die 102 may be approximately 50 microns or less. The thickness 172 of the power and signal connection layer of the first circuit die 104 may be from approximately 2 microns to approximately 3 microns. The total signal distance between the first circuit 134 and the second circuit 146 is substantially reduced over parallel-type circuit architectures where dies are bonded side-by-side and may require further wire bonding techniques for signal connections. The final interposer thickness may be based on density of through silicon vias and via depth. For example, with approximately 20 micron vias, the interposer thickness may be from approximately 100 microns to approximately 200 microns. With sub one micron vias to approximately 4 micron vias, the interposer thickness may be from approximately 5 microns to approximately 10 microns (with additional support on PDN layer).

The dramatic reduction in RC delay (due to the substantially shortened electrical distance between the first circuit 134 and the second circuit 146) for the signals enables exceptionally fast signal transfers. For example, if the first circuit 134 is a logic circuit and the second circuit 146 is a memory circuit, storing and retrieving of data is fast enough to allow further advances in machine learning/artificial intelligence devices that have a heavy load demand on memory during processing tasks. The increased density of connections between the memory and logic circuits also allows a dramatic increase in the number of logical calculations and the like. With higher speeds between the circuits and higher connection densities, thermal issues may arise in the vertical stack 160. In a view 200 of FIG. 2, a vertical stack architecture is formed with a first heatsink 202 bonded to the second circuit die 108 to increase thermal transfer from the second circuit 146 to ambient air. The first heatsink 202 may use fins to increase the surface area of the first heatsink 202 to increase thermal transfer. One or more additional second heatsinks 204 may be embedded in the substrate 110 to allow thermal transfer from the PDN layer 106 into the substrate 110 via solder bumps 142. The optional heatsinks may help regulate the extra thermal energy generated by the faster processing capabilities of the vertical stack architecture.

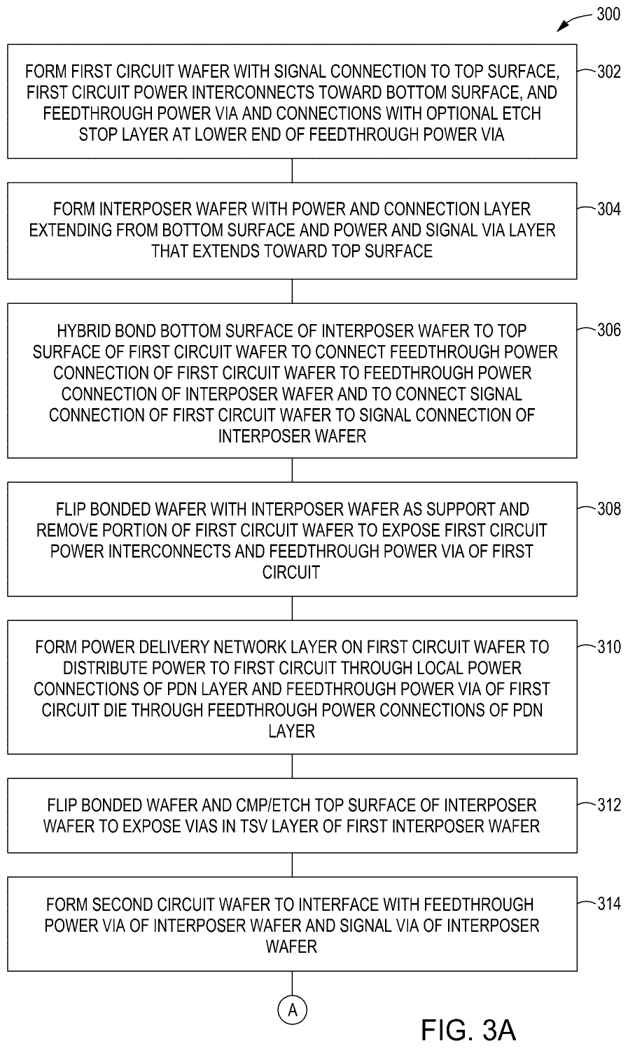

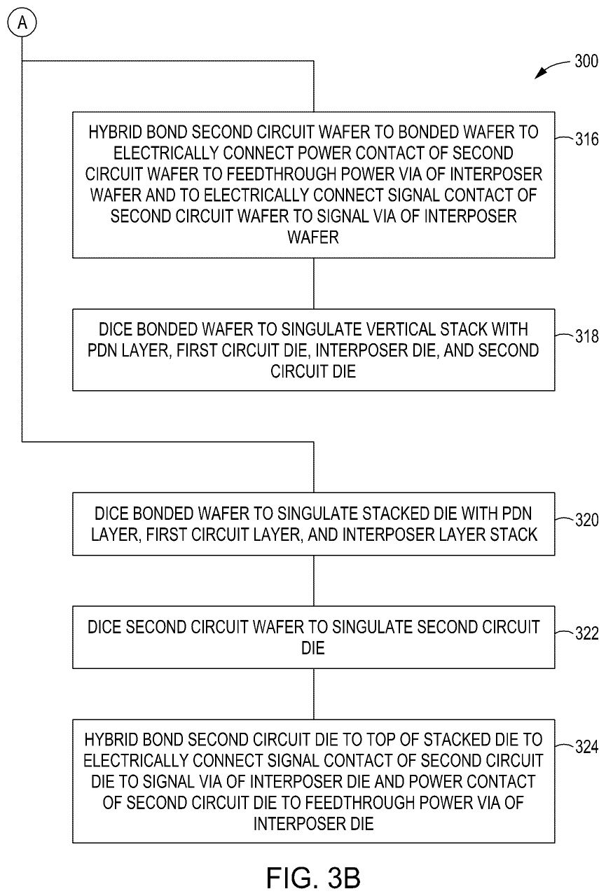

In FIGS. 3A and 3B, a method 300 of forming a vertical stack based on the above vertical stack architecture in accordance with some embodiments is depicted. In brief, wafers are formed, each with multiple copies of dies, that are bonded together along with a PDN layer formed on one of the wafers to form a chip or die stack before being diced apart. The individual dies replicated on each wafer type are designed with connections that align with other dies of other wafer types to allow hybrid bonding to join the wafers as a whole and the die connections together to form electrical connections that traverse more than one wafer type when bonded. One issue in traditional manufacturing is the use of wafers that are too thin to self-support during manufacturing processes and require support wafers to be temporarily bonded and then debonded after completing certain processes. The methods of the present principles eliminate the need for the temporary support wafers by forming wafers that contain dies that are part of the die stack with excess thicknesses that are then reduced after a wafer bonding process. The underlying wafers that become part of the die stack provide the needed support for the subsequent processing.

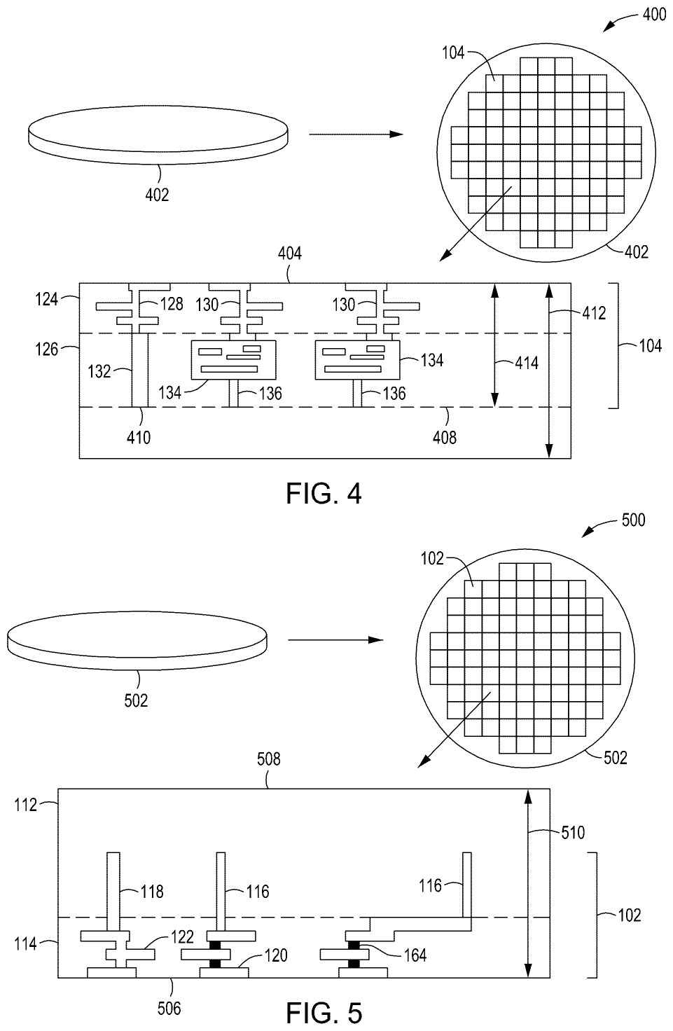

References to FIGS. 1 and 4-13 will be made during the discussion of the method 300. Although the method is described in a particular order, each process is not required to be performed in that exact particular order. For example, all wafers may be pre-formed before bonding of any wafer instead of forming each wafer just prior to bonding that particular wafer and the like. In block 302 and as shown in a view 400 of FIG. 4, a first circuit wafer 402 is formed with one or more signal connections 130 from the first circuit 134 to a top surface 404, one or more first circuit power vias 136 towards a bottom surface 406, and one or more feedthrough power vias 132 and feedthrough power connections 128 with an optional etch stop layer 408 at a lower end 410 of the feedthrough power via 132. In some embodiments, the optional etch stop layer 408 is not used as the first circuit wafer 402 may undergo a mechanical polishing process instead of an etching process to reveal the backside vias. The thickness 412 of the first circuit wafer 402 is thicker than the thickness 414 of the first circuit die 104 to allow handling of the wafer without causing damage to the circuits in each die. In some embodiments, the first circuit wafer 402 may have a starting thickness of approximately 700 microns before any polishing or etching processes. After the first circuit wafer 402 is bonded to another wafer, namely the interposer wafer 502, the excess thickness can be removed as the interposer wafer 502 provides the necessary support. In some embodiments, to increase yield, the first circuit wafer 402 may be tested to ensure that all circuits/dies of the first circuit wafer 402 are functioning correctly. Testing ensures that non-functioning circuits/dies are not eliminated which would cause the failure of other expensive circuits and dies.

In block 304 and as shown in a view 500 of FIG. 5, the interposer wafer 502 is formed with a power and signal connection layer 114 with one or more feedthrough power connection 122 and one or more signal connection 120 with signal altering elements 164 extending to the bottom surface 506 and with a power and signal via layer 112 that extends signal and power vias towards a top surface 508. In some embodiments, the interposer wafer 502 is formed of a low-k dielectric material with electrical connections of a copper material. The signal altering elements 164 may vary depending on the signal shaping characteristics and/or buffering needed from one circuit to another. The interposer wafer 502 has a thickness 510 that is greater than the thickness of the interposer die 102. In some embodiments, the interposer die 102 has a thickness of approximately 700 microns prior to any polishing or etching processes. The increased thickness of the interposer wafer 502 allows the wafer to function as a structural support during subsequent processing (handling, backgrinding, etching, etc.) as well as an interposer. In traditional processes, a support substrate would normally be required to be bonded to provide such support for the first circuit wafer 402 and then the support substrate would have to be removed after thinning of the first circuit wafer 402, increasing production time and costs. The interposer wafer 502 essentially replaces the support substrate and becomes part of the die stack so the interposer wafer 502 does not need to be removed after processing, reducing production time and costs. In some embodiments, to increase yield, the interposer wafer 502 may be tested to ensure that all electronical connections and/or signal altering elements of the interposer wafer 502 are functioning correctly. Testing ensures that non-functioning connections/elements are not used eliminate the failure of other expensive circuits and dies bonded to the interposer wafer 502 and dies.

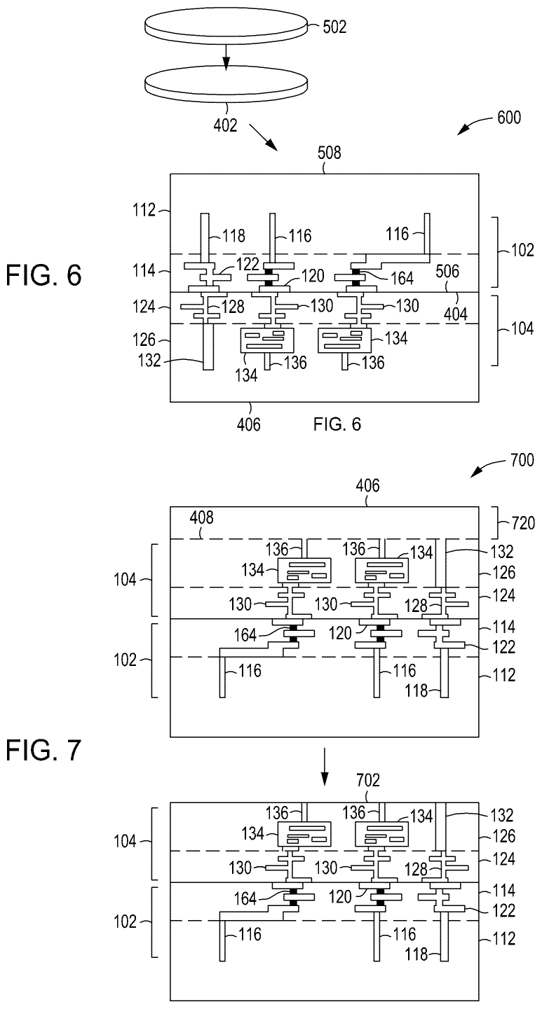

In block 306 as depicted in a view 600 of FIG. 6, the bottom surface 506 of interposer wafer 502 is hybrid bonded to the top surface 404 of the first circuit wafer 402 to connect the feedthrough power connection 128 of the first circuit wafer 402 to the feedthrough power connection 123 of the interposer wafer 502 and to connect the signal connection 130 of the first circuit wafer 402 to the signal connection 120 of the interposer wafer 502. Hereinafter, when wafers are bonded together, the wafers will be referred to as ‘the bonded wafer’ regardless of the number or types of wafers that are bonded together. In block 308 depicted in a view 700 of FIG. 7, the bonded wafer (first circuit wafer 402 bonded to interposer wafer 502) is flipped and with the interposer wafer 502 as support, a portion 720 of the first circuit wafer 402 that acted as a support layer for the first circuit wafer 402 handling is removed to expose the first circuit power via 136 and the feedthrough power via 132 of the first circuit wafer 402. The removal of the portion 720 may be achieved by CMP processes to expose the interconnects and/or vias and/or by etching the first circuit wafer to the optional etch stop layer 408 to expose the interconnects and/or vias on a bottom surface 702 of the first circuit wafer. In some embodiments, the first circuit wafer 402 may be reduced to a thickness of approximately 5 microns to approximately 10 microns. After thinning of the first circuit wafer 402, the first circuit wafer 402 relies on the support of the interposer wafer 502 for support during handling and any subsequent processing.

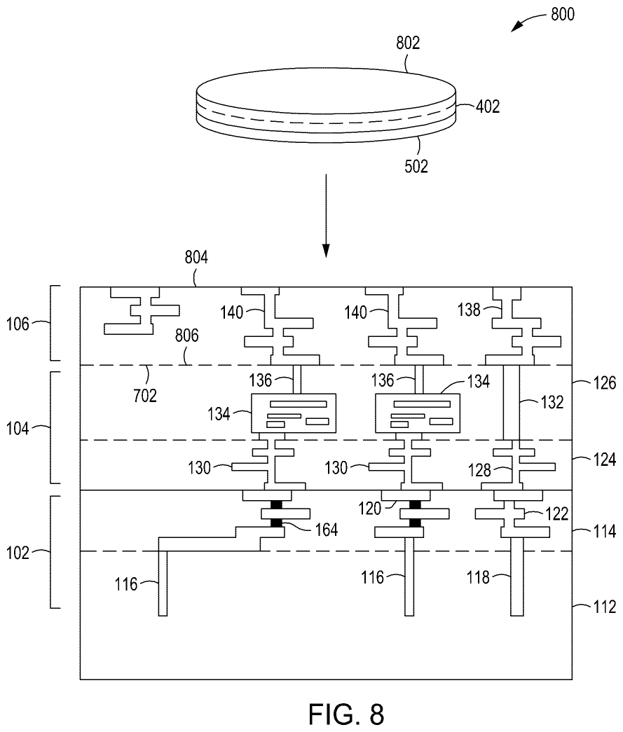

In block 310 as depicted in a view 800 of FIG. 8, a PDN layer 802 is formed directly on the bottom surface 702 of the first circuit wafer 402 to distribute power to the first circuit 134 through local power connections 140 of the PDN layer 802 and the feedthrough power via 132 of the first circuit die 104 through feedthrough power connection 138 of the PDN layer 802. Since the stack is flipped, the top is the bottom surface 804 of the PDN layer 802. In some embodiments, the PDN layer 802 is deposited on the first circuit wafer 402 through multiple processes to form vias, redistribution layers, and connections and the like directly on the first circuit wafer 402 for power delivery to the die stack. In some embodiments, the PDN layer 802 may be formed on a wafer with multiple PDN die and then bonded to the first circuit wafer 402. However, forming the PDN layer 802 on the first circuit wafer 402 is more economical and generally easier as the processes required are part of back end of line (BEOL) packaging processes. In some embodiments, the BEOL processes may include dielectric deposition, trench/via (dual damascene) formation, barrier layer formation, copper gapfill depositions, and CMP processes. By repeating the BEOL processes over a few layers, a power delivery network is formed on the backside of the first circuit wafer.

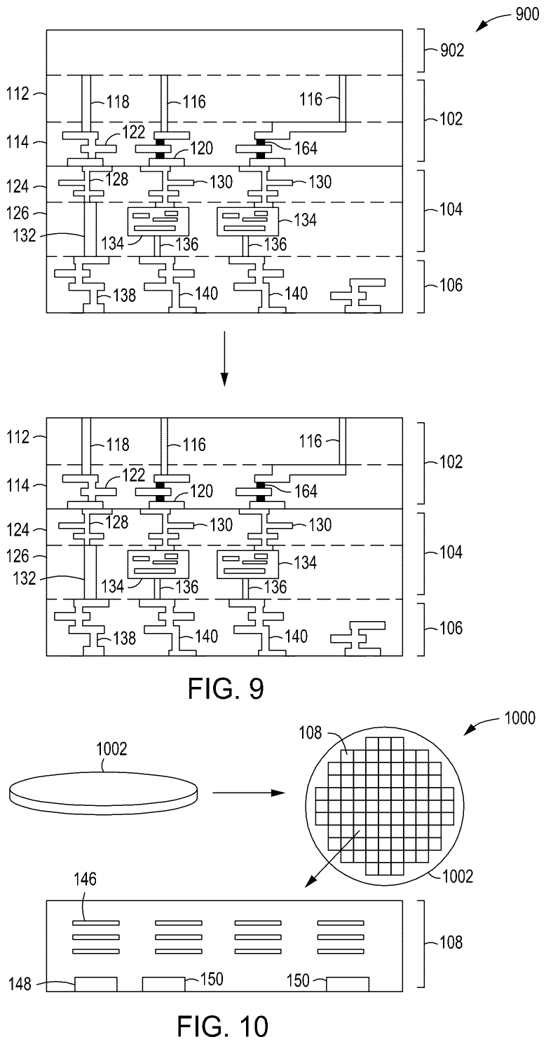

In block 312 as depicted in a view 900 of FIG. 9, the bonded wafer (PDN layer 802, first circuit wafer 402, interposer wafer 502) is flipped and a portion 902 of the top surface of the interposer wafer 502 acting as a support layer for the bonded wafer is removed to expose the signal vias 116 of the interposer wafer 502 and the feedthrough power via 118 of the interposer wafer 502. The removal of the portion 902 may be achieved by CMP processes and/or etching processes and the like. In some embodiments, the interposer wafer 502 can be reduced in thickness to approximately 100 microns to approximately 300 microns. In some embodiments, the interposer wafer 502 can be reduced to a thickness of approximately 100 microns to approximately 200 microns. If an additional supporting substrate (temporary substrate that is bonded and debonded) is adhered to the bonded wafer, the interposer wafer 502 can be reduced to a thickness of approximately 50 microns or less.

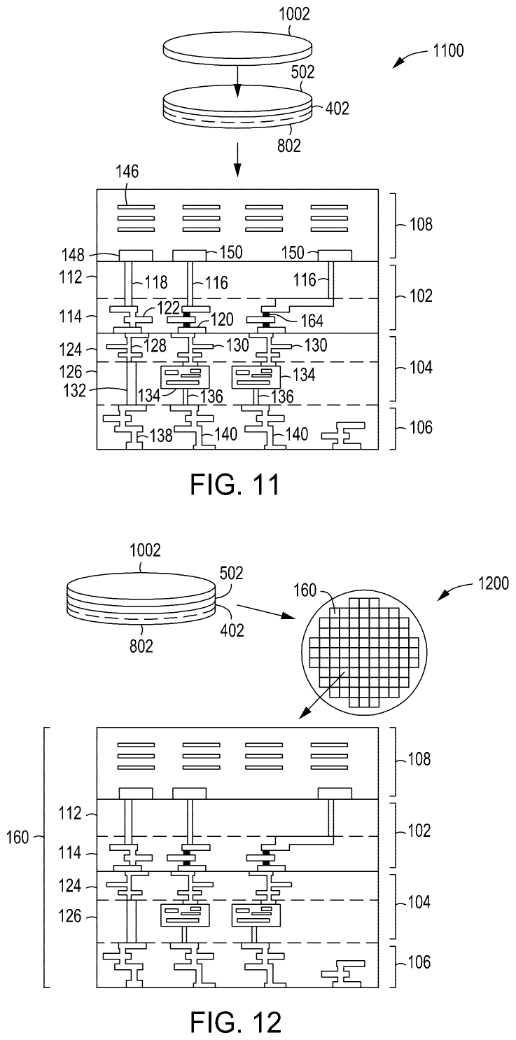

In block 314 as depicted in a view 1000 of FIG. 10, a second circuit wafer 1002 is formed that will interface with the feedthrough power via 118 of the interposer wafer 502 and the signal vias 116 of the interposer wafer 502. In some embodiments, the second circuit wafer 1102, similar to the first circuit wafer 402, may undergo several processing steps prior to or after bonding (e.g., testing, thinning, etc.). After block 314, the method 300 may be performed in two alternative ways as depicted in FIG. 3B. The first alternative method for completing a vertical stack 160 is to hybrid bond the second circuit wafer 1102 to the bonded wafer as a whole wafer per block 316 of the method 300. In some embodiments, the second circuit wafer 1002 may be optionally formed with excess thickness to better withstand handling and processing. If so, the excess thickness may be reduced after bonding the second circuit wafer 1002 to the bonding wafer. The bonding of the second circuit wafer 1002 to the bonded wafer as depicted in a view 1100 of FIG. 11 electrically connects the power contact 148 of the second circuit wafer 1002 to the feedthrough power via 118 of the interposer wafer 502 and electrically connects the signal contacts 150 of the second circuit wafer 1002 to the signal vias 116 of the interposer wafer 502. In block 318 as depicted in a view 1200 of FIG. 12, the bonded wafer is then diced to singulate the vertical stack 160 as a whole that includes the PDN layer 106, the first circuit die 104, the interposer die 102, and the second circuit die 108. The vertical stack 160 can then be further processed and connected, for example, to substrate 110 with or without heatsinks. Power for operating the second circuit die 108 originates through the backside through the PDN layer 106.

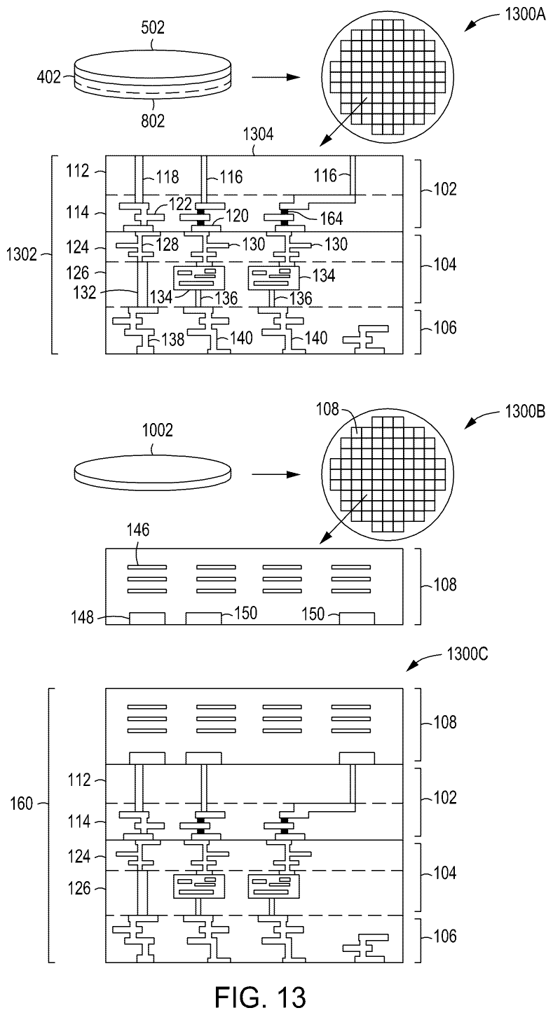

In the alternative after block 314, in block 320, the bonded wafer can be diced to singulate a stacked die 1302 with a PDN layer 106, a first circuit die 104, and an interposer die 102 as depicted in a view 1300A of FIG. 13. In block 320, the second circuit wafer 1002 is diced to singulate the second circuit die 108 as depicted in a view 1300B of FIG. 13. In block 324 as depicted in a view 1300C of FIG. 13, the second circuit die 108 is bonded to a top surface 1304 of the stacked die 1302 forming the vertical stack 160. In some embodiments, the stacked die 1302 may need to be adhered to the substrate 110 for support prior to the bonding of the second circuit die 108 to the stacked die 1302. The bonding of the second circuit die 108 to the stacked die 1302 electrically connects the power contact 148 of the second circuit die 108 to the feedthrough power via 118 of the interposer die 102 and electrically connects the signal contacts 150 of the second circuit die 108 to the signal vias 116 of the interposer die 102. Power for operating the second circuit die 108 originates from the backside through the PDN layer 106.

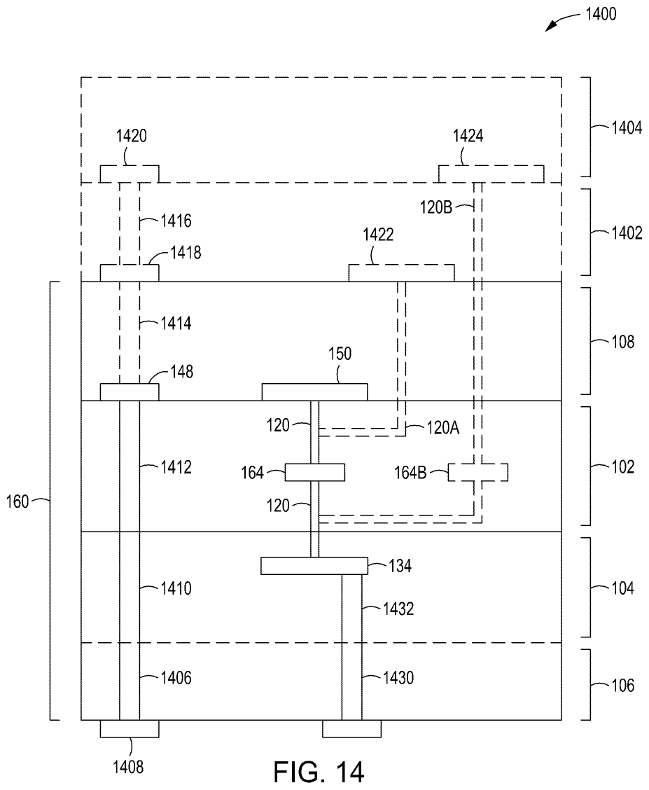

In addition, the above methods can be used to increase the number of dies in the vertical stack 160 as depicted in a view 1400 of FIG. 14. A third circuit wafer may be formed to produce a third circuit die 1402 that may be bonded to the second circuit die 108. A fourth circuit wafer may be formed to produce a fourth circuit die 1404 bonded to the third circuit die 1402 and so forth. The vertical stack 160 provides a first backside power path 1406 through the PDN layer 106 from an external connection 1408 to a backside power source (not shown). The backside power path is further extended with a second backside power path 1410 through the first circuit die 104 and a third backside power path 1412 through the interposer die 102. If the third circuit die 1402 is added to the vertical stack 160, a fourth backside power path 1414 can be formed through the second circuit die 108, optionally extending from the power contact 148 of the second circuit die 108. Similarly, if the fourth circuit die 1404 is added to the vertical stack 160, a fifth backside power path 1416 can be formed through the third circuit die 1402, optionally extending from a feedthrough power connection 1418 of the third circuit die 1402 to a feedthrough power connection 1420 of the fourth circuit die 1404. In the example, the numbers of die can be increased and powered accordingly by providing a backside power path through each of the dies. In addition to the backside power paths, the PDN layer 106 also includes a first local circuit power path 1430. The first local circuit power path 1430 is electrically connected to a second local circuit power path 1432 of the first circuit die 104 to provide power to the first circuit 134.

Signals provided to and from the first circuit 134 can also be extended to upper dies in the vertical stack 160. The first circuit die 104 can have more than one first circuit 134 but only one is depicted to keep the discussion brief. A signal connection 120 is provided through the interposer die 102 via signal altering elements 164 to the signal contact 150 of the second circuit die 108. If a third circuit die 1402 is added and functions, for example, as additional memory similar to the second circuit die 108, an optional first signal pathway 120A may be added in the interposer die 102 and the second circuit die 108 to provide a signal pathway to a signal contact 1422 of the third circuit die 1402 after the signal altering elements 164 of the interposer die 102. In some embodiments, the optional first signal pathway 120A may originate from within the second circuit die 108 (e.g., signal contact 150, etc.) and traverse the second circuit die 108 to the third circuit die 1402.

However, if the signals from the first circuit die 104 require different signal altering, the interposer die 102 may have optional signal altering elements 164B in an optional second signal pathway 120B from the first circuit 134 through the second circuit die 108 and the third circuit die 1402 to a signal contact 1424 of the fourth circuit die 1404. The example is not meant to be limiting and is depicts the flexibility of the architecture to continually add addition dies with minimal impacts to the underlying dies. The underlying dies will have an additional backside power pathway segment and, in some embodiments, an additional signal pathway or two depending on the number of dies added to the vertical stack 160. The interposer die 102 may also have additional signal altering elements and signal pathways. The additional signal pathway distance (RC delay) for each added circuit will be the thicknesses of the underlying circuits between the added circuit and the first circuit 134.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for forming a multiple die stack, comprising:
forming a first circuit wafer with multiple first circuit dies and a first circuit support layer on a bottom of the first circuit wafer, each first circuit die has a power and circuit layer underlying a power and signal layer;
forming an interposer wafer with multiple interposer dies and an interposer support layer on a top of the interposer wafer, each interposer die has a power and signal layer underlying a power via and signal via layer; and
hybrid bonding a top surface of the first circuit wafer to a bottom surface of the interposer wafer to form a first bonded wafer with electrical power and signal connections between the multiple first circuit dies and the multiple interposer dies, wherein the interposer wafer provides structural support of the first bonded wafer during subsequent processing.

2. The method of claim 1, further comprising:
flipping the first bonded wafer to expose the first circuit support layer of the first circuit wafer; and
performing a first chemical mechanical polishing (CMP) process or a first etching process on the first circuit wafer to remove the first circuit support layer to expose a plurality of power vias in the power and circuit layer of the first circuit wafer.

3. The method of claim 2, further comprising:
forming a power delivery network (PDN) layer directly on the first circuit wafer, the PDN layer having a top surface with internal power contacts interfacing with the power and circuit layer of the first circuit wafer and a bottom surface with external power contacts, wherein the internal power contacts of the PDN layer make contact with the power and circuit layer to electrically connect the internal power contacts of the PDN layer to the plurality of power vias in the power and circuit layer of the first circuit wafer to form a second bonded wafer from the first bonded wafer.

4. The method of claim 3, further comprising:
flipping the second bonded wafer to expose the top surface of the interposer wafer; and
performing a second CMP process or a second etching process on the interposer support layer to expose contact points of the power via and signal via layer of the interposer wafer.

5. The method of claim 4, further comprising:
reducing the interposer wafer to a total thickness of approximately 100 microns to approximately 200 microns when using vias with a critical dimension of approximately 5 microns to approximately 20 microns.

6. The method of claim 4, further comprising:
reducing the interposer wafer to a total thickness of approximately 5 microns to approximately 10 microns when using vias with a critical dimension of approximately 2 microns to approximately 4 microns.

7. The method of claim 4, further comprising:
forming a second circuit wafer with multiple second circuit dies, each second circuit die having a bottom surface with at least one signal contact and at least one power contact for electrically interconnecting with the multiple interposer dies of the interposer wafer.

8. The method of claim 7, further comprising:
hybrid bonding the bottom surface of the second circuit wafer to the top surface of the interposer wafer to form a third bonded wafer from the second bonded wafer to electrically connect the at least one signal contact and the at least one power contact to the multiple interposer dies of the interposer wafer; and
dicing the third bonded wafer to form electrically connected vertical die stacks, each vertical die stack has one portion of the PDN layer, one of the first circuit die, one of the interposer die, and one of the second circuit die to form a complete vertical die stack with backside power capability.

9. The method of claim 8, further comprising:
forming a heatsink in contact with the second circuit die to remove heat from underlying circuits.

10. The method of claim 8, further comprising:
forming at least one heat sink for an external power contact of the PDN layer in a substrate with contacts for electrically connecting with the PDN layer; and
electrically connecting the PDN layer to the substrate.

11. The method of claim 7, further comprising:
dicing the second bonded wafer after performing the second CMP process or the second etching process to form partial vertical die stacks that are electrically connected from the second bonded wafer;
dicing the second circuit wafer to form second circuit dies; and
hybrid bonding one of the second circuit dies to one of the partial vertical die stacks to form a complete vertical die stack with backside power capability.

12. The method of claim 11, further comprising:
forming a heatsink in contact with the second circuit die to remove heat from underlying circuits.

13. The method of claim 11, further comprising:
forming at least one heat sink for an external power contact of the PDN layer in a substrate with contacts for electrically connecting with the PDN layer; and
electrically connecting the PDN layer to the substrate.

14. A method for forming a multiple die stack, comprising:
forming a first circuit wafer with multiple first circuit dies and a first circuit support layer on a bottom of the first circuit wafer, each first circuit die has a power and circuit layer underlying a power and signal layer;
forming an interposer wafer with multiple interposer dies and an interposer support layer on a top of the interposer wafer, each interposer die has a power and signal layer underlying a power via and signal via layer;
hybrid bonding a top surface of the first circuit wafer to a bottom surface of the interposer wafer to form a first bonded wafer with electrical power and signal connections between the multiple first circuit dies and the multiple interposer dies, wherein the interposer wafer provides structural support of the first bonded wafer during subsequent processing;
flipping the first bonded wafer to expose the first circuit support layer of the first circuit wafer;
performing a first chemical mechanical polishing (CMP) process or a first etching process on the first circuit wafer to remove the first circuit support layer to expose a plurality of power vias in the power and circuit layer of the first circuit wafer;
forming a power delivery network (PDN) layer directly on the first circuit wafer, the PDN layer having a top surface with internal power contacts interfacing with the power and circuit layer of the first circuit wafer and a bottom surface with external power contacts, wherein the internal power contacts of the PDN layer make contact with the power and circuit layer to electrically connect the internal power contacts of the PDN layer to the plurality of power vias in the power and circuit layer of the first circuit wafer to form a second bonded wafer from the first bonded wafer;
flipping the second bonded wafer to expose the top surface of the interposer wafer;
performing a second CMP process or a second etching process on the interposer support layer to expose contact points of the power via and signal via layer of the interposer wafer such that a thickness of the interposer wafer is approximately 100 microns to approximately 200 microns;
forming a second circuit wafer with multiple second circuit dies, each second circuit die having a bottom surface with at least one signal contact and at least one power contact for electrically interconnecting with the multiple interposer dies of the interposer wafer;
hybrid bonding the bottom surface of the second circuit wafer to the top surface of the interposer wafer to form a third bonded wafer from the second bonded wafer to electrically connect the at least one signal contact and the at least one power contact to the multiple interposer dies of the interposer wafer; and
dicing the third bonded wafer to form electrically connected vertical die stacks, each vertical die stack has one portion of the PDN layer, one of the first circuit die, one of the interposer die, and one of the second circuit die to form a complete vertical die stack with backside power capability.

15. The method of claim 14, further comprising:
forming a heatsink in contact with the second circuit die to remove heat from underlying circuits.

16. The method of claim 14, further comprising:
forming at least one heat sink for an external power contact of the PDN layer in a substrate with contacts for electrically connecting with the PDN layer; and
electrically connecting the PDN layer to the substrate.

17. A die stack with a vertical architecture comprising:
a power delivery network (PDN) layer with a first backside power path and a first circuit power path;
a first circuit die with a first circuit, a second circuit power path electrically connected to the first circuit and the first circuit power path of the PDN layer, a second backside power path electrically connected to the first backside power path of the PDN layer, and a first signal path electrically connected to the first circuit;
an interposer die with a third backside power path electrically connected to the second backside power path of the first circuit die and a second signal path electrically connected to the first signal path of the first circuit die; and
a second circuit die with a power contact electrically connected to the third backside power path of the interposer die and a signal contact electrically connected to the second signal path of the interposer die.

18. The die stack of claim 17, wherein the interposer die further includes a signal altering element interposed in the second signal path that electrically alters signal characteristics of signals traveling on the second signal path prior to reaching the second circuit die.

19. The die stack of claim 17, wherein the first circuit die includes a plurality of first circuits and a plurality of first signal paths and a plurality of second circuit power paths and wherein the PDN layer includes a plurality of first circuit power paths that are electrically connected to the plurality of second circuit power paths in the first circuit die.

20. The die stack of claim 17, further comprising:
a heatsink in thermal contact with a top surface of the second circuit die.
